(19) United States
(12) Patent Application Publication
(10) Pub. No.: US 2013/0200342 A1
(43) Pub. Date: Aug. 8, 2013

(54) DISPLAY APPARATUS

(71) Applicants: Sangmin YI, Suwon-si (KR); Seung Yo YANG, Suwon-si (KR); Keun-dong HA, Seongnam-si (KR)

(72) Inventors: Sangmin YI, Suwon-si (KR); Seung Yo YANG, Suwon-si (KR); Keun-dong HA, Seongnam-si (KR)

(21) Appl. No.: 13/709,177

(22) Filed: Dec. 10, 2012

(30) Foreign Application Priority Data
Feb. 2, 2012 (KR) 10-2012-0010944

(51) Int. Cl. H01L 27/32

(52) U.S. Cl. CPC H01L 27/3272
USPC 257/40

(57) ABSTRACT

A display apparatus including a display panel including an array substrate and display unit on the array substrate; a polarizing film on one surface of the display panel; and a deformation prevention member on another surface of the display panel, the other surface being opposite to the one surface on which the polarizing film is disposed, the deformation prevention member preventing deformation of the display panel.

### CROSS-REFERENCE TO RELATED APPLICATION

Korean Patent Application No. 10-2012-0010944, filed on Feb. 2, 2012, in the Korean Intellectual Property Office and entitled, “Display Apparatus,” is hereby incorporated by reference in its entirety.

### BACKGROUND

1. Field

Embodiments relate to a display apparatus.

2. Description of the Related Art

A display apparatus, e.g., a liquid crystal display (LCD) or an organic light emitting diode (OLED) display, may include a polarizing film on a display panel to enhance image display performance.

### SUMMARY

Embodiments provide a display apparatus. In some embodiments, the display apparatus may include a display panel including an array substrate and a display unit, e.g., an organic light emitting diode (OLED), disposed on the array substrate, a polarizing film disposed on one surface of the display panel, and a deformation prevention member disposed on a surface opposite to the surface on which the polarizing film is disposed and configured to prevent deformation of the display panel.

According to an example embodiment, the deformation prevention member may be a film made of either one of a polyethylene terephthalate (PET) based material and an acryl-based material.

According to an example embodiment, the deformation prevention member may be a film made of at least one of polyimide (PI), poly(p-xylene) polymer (e.g., Parylene), polymethylmethacrylate (PMMA), polyvinylalcohol (PVA), and polyvinylphenol (PVP).

According to an example embodiment, the deformation prevention member may be a transparent deposition film where at least one of amorphous silicon (a-Si) and silicon nitride (SiNx) is deposited on a surface disposed in a direction facing the light-emitting surface of the display panel.

According to an example embodiment, the deformation prevention member may be disposed on a surface disposed in a direction facing the light-emitting surface of the display panel.

According to an example embodiment, the deformation prevention member may be disposed between the display panel and the polarizing film.

### BRIEF DESCRIPTION OF THE DRAWINGS

Features will become apparent to those of ordinary skill in the art by describing in detail exemplary embodiments with reference to the attached drawings in which:

FIG. 1 illustrates an exploded perspective view of a display apparatus according to an embodiment.

FIG. 2 illustrates a partial cross-sectional view of the display apparatus shown in FIG. 1.

FIG. 3 illustrates a graph showing average flatness levels measured when only a polarizing film is attached to a display panel and when a polarizing film and a deformation prevention member are attached to a display panel.

FIG. 4 illustrates a cross-sectional view of a display apparatus according to an embodiment.

FIG. 5 illustrates a cross-sectional view of a display apparatus according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. Like reference numerals refer to like elements throughout. As used herein, the term “and/or” includes any and all in a mixture of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in tile figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized embodiments (and intermediate structures) of the inventive concept. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the embodiments.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

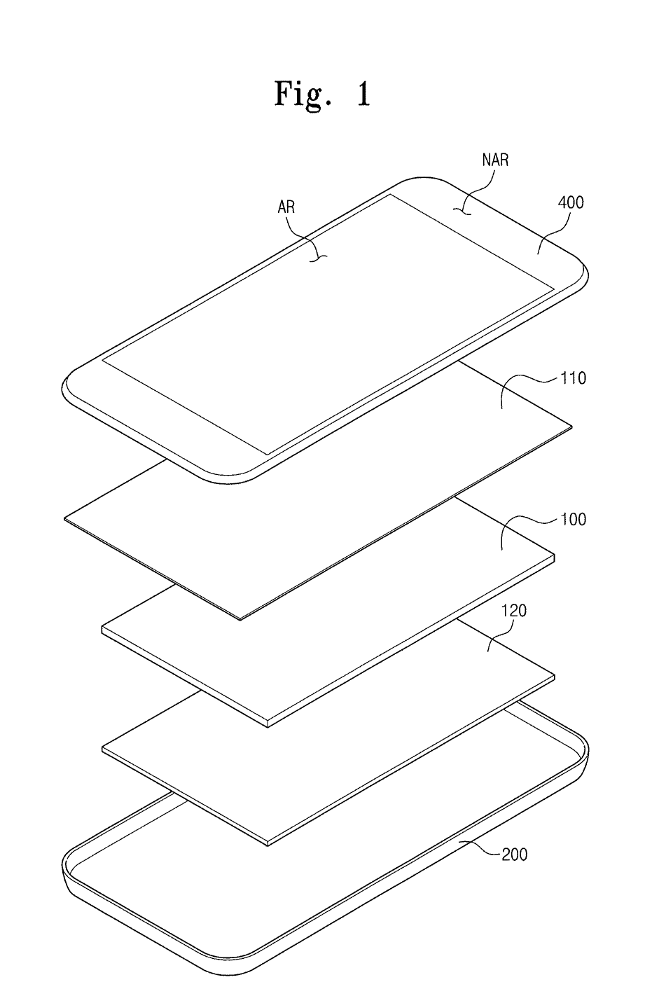

FIG. 1 illustrates an exploded perspective view of a display apparatus according to an embodiment. The display panel may include a display panel 100, a housing 200 configured to accommodate the display panel 100, a window member 400 on the display panel 100, a polarizing film 110 between the display panel 100 and the window member 400, and a deformation prevention member 120 between the display panel 100 and the housing 200.

The display panel 100 displays images. The display panel 100 may employ various types of display panels or display units. For example, the display panel 100 may employ a self-luminous display panel, e.g., an organic light emitting display (OLED) panel or a plasma display panel (PDP). In an implementation, the display panel 100 may employ a non self-luminous display panel, e.g., a liquid crystal display (LCD) panel, an electrophoretic display (EPD) panel, and an electrowetting display (EWD) panel. In the case that the display panel 100 employs a non self-luminous display panel, it may include a backlight unit (BLU). For ease of explanation, an OLED will be described as the display panel 100.

The housing 200 may accommodate the display panel 100. As shown in FIG. 1, the housing 200 may include one member configured to define a space in which the display panel 100 is accommodated. However, the embodiments are not limited thereto, and the housing 200 may include at least two members combined with each other. In the present embodiment, the housing 200 including one member will be exemplarily described.

In addition to the display panel 100, the housing 200 may further accommodate a printed circuit board (PCB) on which a plurality of active elements (not shown) and/or a plurality of passive elements (not shown) are mounted. In an implementation, the housing 200 may further accommodate a power supply (not shown) such as a battery.

The polarizing film 110 may be between the display panel 100 and the window member 400 to help enhance image display performance.

The deformation prevention member 120 may be between the display panel 100 and the housing 200 to help reduce and/or prevent deformation of the display panel 100. For example, the deformation prevention member 120 may support the display panel 100 to help prevent deformation of the display panel 100 that could result from a stress externally applied to the display panel 100.

The window member 400 may be disposed on an image display side of the display panel 100. The window member 400 may be combined or coupled with the housing 200 to constitute an outer surface of the display apparatus.

When viewed from a top side, the window member 400 may include a display region AR (in which an image generated from the display panel 100 is displayed) and a non-display region NAR (adjacent to at least one portion of the display panel AR). In the non-display region NAR, the image may not be displayed.

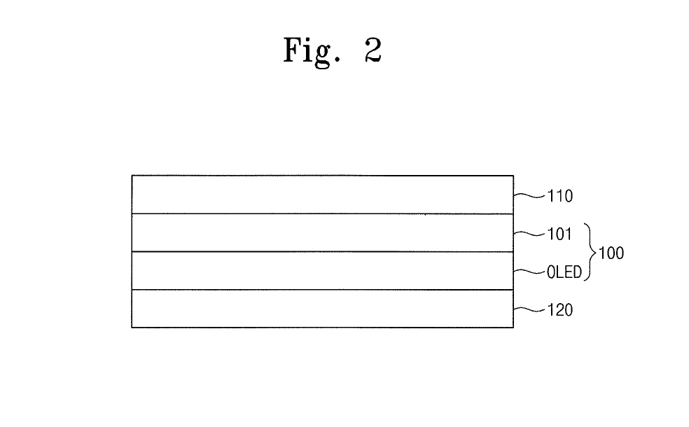

FIG. 2 illustrates a partial cross-sectional view of the display apparatus shown in FIG. 1. FIG. 2 only illustrates a display panel, a polarizing film, and a deformation prevention member. The display apparatus may include the polarizing film 110 (disposed on at least one surface of the display panel 100) and the deformation prevention member 120 (to help reduce and/or prevent deformation of the display panel 100 caused by the polarizing film 110).

The display panel 100 may include an array substrate 101 (in which a scan line, a data line, a power supply line, a switching thin film transistor, and a driving thin film transistor are disposed) and an organic light emitting diode (OLED) on the array substrate 101.

Additionally, at least one surface of the display panel 100 may be a light-emitting surface. The light-emitting surface may be determined depending on a shape of the OLED.

For example, the OLED may include a first electrode (not shown) connected to the driving thin film transistor, a second electrode (not shown) facing the first electrode, and an organic film (not shown) between the first electrode and the second electrode.

If the OLED is a bottom-emission OLED, the first electrode may transmit light generated from the organic film, and the second electrode may reflect the light generated from the organic film. The first electrode may include transparent conductive oxide, e.g., indium tin oxide (ITO), indium zinc oxide (IZO), aluminum zinc oxide (AZO), gallium-doped zinc oxide (GZO), zinc tin oxide (ZTO), gallium tin oxide (GTO), and/or fluorine-doped tin oxide (FTO). The second electrode may include at least one selected from the group of molybdenum (Mo), molybdenum tungsten (MoW), chrome (Cr), aluminum (Al), aluminum neodymium (AlNd), and aluminum alloy (Al-alloy). Accordingly, the light-emitting surface of the display panel 100 may be a surface exposed to the outside of the array substrate 101.

If the OLED is a top-emission OLED, the first electrode may reflect light generated from the organic film, and the second electrode may transmit the light generated from the organic film. The first electrode may include a first conductive layer (not shown) including a conductive metal capable of reflecting light and a second conductive layer (not shown) including the transparent conductive oxide. The second electrode may include a third conductive layer (not shown) including at least one selected from the group of Mg, Ca, Al, Ag, Ba, and alloys thereof and a fourth conductive layer (not shown) including the transparent conductive oxide. The third conductive layer may have a thickness sufficient to transmit the light generated from the organic film. Accordingly, the light-emitting surface of the display panel 100 may be a surface exposed to the outside of the OLED.

If the OLED is a both-side-emission OLED, both the first electrode and the second electrode may be configured to transmit the light generated from the organic film. Accordingly, if the OLED is the both-side-emission OLED, both surfaces of the display panel 100 may be light-emitting surfaces.

The organic film may include at least an emission layer (EML) and may generally have a multiple thin film structure. For example, the organic film may include a hole injection layer (HIL) for injecting a hole, a hole transport layer (HTL) having a superior transportation characteristic and blocking migration of unbound electros at the EML to increase a change of hole-electron rebinding, the EML emitting light by rebinding the injected electrons to holes, a hole blocking layer (HBL) for suppressing migration of unbound holes at the EML, an electron transport layer (ETL) for smoothly transporting the electrons to the EML, and an electron injection layer (EIL) for injecting the electrons.

The polarizing film 110 may be disposed on at least one surface of the display panel 100, e.g., the light-emitting surface of the display panel 100, to help improve image display performance of the display panel 100. The polarizing film 110 may include, e.g., a polyvinyl alcohol (PVA), and may be a thin film stretched in a uniaxial or biaxial direction.

The deformation prevention member 120 may be disposed on a surface facing or opposite to the light-emitting surface of the display panel 100. For example, the deformation prevention member 120 may be disposed on a surface opposite to the surface on which the polarizing film 110 is disposed.

The deformation prevention member 120 may be a film formed of at least one of a polyethylene terephthalate (PET)-based material, an acryl-based material, or the like, and may be in an unstretched state.

In an implementation, the deformation prevention member 120 may be a transparent organic material film formed of at least one of a polyimide (PI), a poly(p-xylene) polymer (e.g., Parylene), polymethylmethacrylate (PMMA), a polyvinylalcohol (PVA), a polyvinylphenol (PVP), or the like.

In an implementation, the deformation prevention member 120 may be a transparent deposition film in which at least one selected from the group of amorphous silicon (a-Si), silicon nitride (SiNx), or the like is deposited on a surface disposed in a direction facing or opposite to the light-emitting surface of the display panel 100.

In the display apparatus according to the present embodiment, the deformation prevention member 120 may help reduce and/or prevent deformation of the display panel 100.

For example, the stretched polarizing film 110 may have a restoring force, e.g., causing it to contract. Accordingly, the polarizing film 110 may continue to apply a stress to the display panel 100 after being attached to the display panel 100. Thus, the display panel 100 may be deformed due to the stress.

The deformation prevention member 120 may be on the surface opposite to the light-emitting surface of the display panel 100 to support the display panel 100. Thus, the deformation prevention member 120 may help reduce and/or prevent the deformation of the display panel 100 caused by stress.

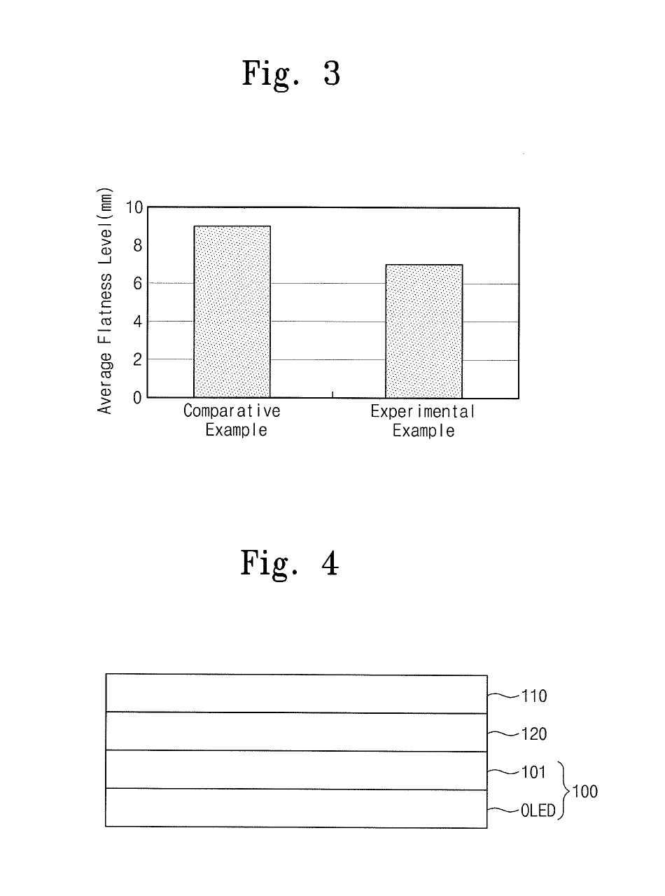

FIG. 3 illustrates a graph showing average flatness levels measured when only a polarizing film was attached to a display panel and when a polarizing film and a deformation prevention member were attached to a display panel. FIG. 3 and Table 1, below, show a graph and data of flatness levels measured when only a polarizing film was attached to a display panel and when a polarizing film and a deformation prevention member were attached to a display panel. The display panel was an OLED panel whose diagonal length was 55 inches and thickness was 1.1 millimeter. The polarizing film was made of PVA and was uniaxially stretched in a long side direction of the display panel and had a thickness of 50 micrometers.

The Comparative Example was a case where only the polarizing film was attached onto a light-emitting surface of the display panel, while the Experimental Example was a case where the polarizing film was attached onto the light-emitting surface of the display panel and the deformation prevention member was attached onto a surface disposed in a direction facing or opposite to the light-emitting surface of the display panel.

In Table 1, the average flatness level was an average obtained by measuring both the Comparative Example and the Experimental Example three times.

TABLE 1
Measurement of Flatness Level of Display Panel

| | | Comparative Example | Experimental Example |
|---|---|---|---|
| Flatness | Average | 9.12 | 6.72 |
| Level (mm) | Maximum | 14.53 | 11.18 |
| | Minimum | 0.39 | 0.3 |

With reference to FIG. 3 and Table 1, there will now be described the Comparative Example (in which only a polarizing film 110 was attached to a display panel 100). As may be seen in FIG. 3 and Table 1, a flatness level based on the deformation of the display panel 100 resulting from the polarizing film 110 had a maximum 14.53 millimeters and a minimum of 0.39 millimeter. In addition, an average flatness level of the display panel was 9.12 millimeters in the Comparative Example.

Next, there will be described the Experimental Example (in which both a polarizing film 110 and a deformation prevention member 120 were attached to a display panel 100). As may be seen in FIG. 3 and Table 1, a flatness level based on the deformation of the display panel 100 resulting from the polarizing film 110 had a maximum 11.18 millimeters and a minimum of 0.3 millimeter. In addition, an average flatness level of the display panel was 6.72 millimeters in the Experimental Example.

For example, as compared to the Comparative Example, the Experimental Example shows that the maximum flatness level, the minimum flatness level, and the average flatness level based on deformation of the display panel 100 resulting from the polarizing film 110 were all reduced. In particular, it may be seen that the average flatness level in the Experimental Example was about 70 percent of the average flatness level in the Comparative Example. For example, it may be seen that in the amount of deformation of the display panel 100 resulting from the polarizing film 110, the Experimental Example was smaller than the Comparative Example.

Without being bound by theory, this may be because a PET film used as the deformation prevention member 120 may help suppress the deformation of the display panel 100.

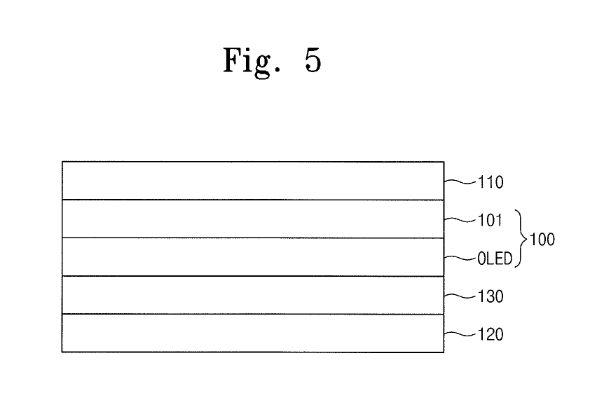

Other embodiments will now be described below with reference to FIGS. 4 and 5. FIG. 4 illustrates a cross-sectional view of a display apparatus according to an embodiment. FIG. 5 illustrates a cross-sectional view of a display apparatus according to an embodiment. In FIGS. 4 and 5, the same elements as those in FIGS. 1 and 3 are designated by the same reference numerals and a repeated description thereof may be omitted. Moreover, in FIGS. 4 and 5, sections different from FIGS. 1 and 3 will be extensively described to avoid duplicate description.

Reference is made to FIG. 4, which illustrates a cross-sectional view of a display apparatus according to an embodiment. As may be seen in FIG. 4, the display apparatus may include a display panel 100, a polarizing film 110, and a deformation prevention member 120. The deformation prevention member 120 may be between the display panel 100 and the polarizing film 110. The deformation prevention member 120 may be transparent to allow light to pass therethrough.

In the display device according to the present embodiment, the deformation prevention member 120 may help reduce and/or prevent deformation of the display panel 100. For example, the stretched polarizing film 110 may have a restoring force and thus may contract.

The deformation prevention member 120 may be between the display panel 100 and the polarizing film 110 to help reduce or alleviate transfer of stress caused by the restoring force of the polarizing film 110 to the display panel 100.

As a result, the deformation prevention member 120 may help reduce and/or prevent the deformation of the display panel 100 which arises from the stress transferred to the display panel 100.

Reference is made to FIG. 5, which illustrates a cross-sectional view of a display apparatus according to an embodiment. As shown in FIG. 5, the display apparatus may include a display panel 100, a polarizing film 110, and a deformation prevention member 120. The display apparatus may further include an encapsulation member 130 that isolates an OLED of the display panel 100 from an external environment. The deformation prevention member 120 may face or may be opposite to a light-emitting surface of the display panel 100, and the encapsulation member 130 may be between the display panel 100 and the deformation prevention member 120.

The encapsulation member 130 may cover the OLED and may include any one of an insulating substrate and a metal cover. If the encapsulation member 130 includes the metal cover, the display panel 100 may emit light in a direction opposite to a direction in which the encapsulation member 130 is disposed. For example, a light-emitting surface of the display panel 100 may be a surface exposed to the outside of an array substrate 101. In an implementation, if the encapsulation member 130 includes the metal cover, light generated from the OLED may be reflected by the metal cover. Thus, optical efficiency of the display panel 100 may be enhanced.

The encapsulation member 130 may include a coating film covering the OLED with an insulating organic material. The coating film may have a multi-layer structure including the insulating organic material.

In the display apparatus according to the present embodiment, the deformation prevention member 120 and the encapsulation member 130 may support the display panel 100 to help reduce and/or prevent deformation of the display panel 100.

By way of summation and review, the polarizing film may be attached to the display panel while being stretched in a uniaxial or biaxial direction by a stretching process. Accordingly, the polarizing film may have a restoring force causing it to contract in a direction opposite to the stretched direction. The restoring force may apply a stress to the display panel. When the above-mentioned polarizing film is applied to the display panel using a thin film as a substrate, the display panel may be warped due to the restoring force.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display apparatus, comprising:
a display panel including an array substrate and display unit on the array substrate;
a polarizing film on one surface of the display panel; and
a deformation prevention member on another surface of the display panel, the other surface being opposite to the one surface on which the polarizing film is disposed, the deformation prevention member preventing deformation of the display panel.

2. The display apparatus as set forth in claim 1, wherein the deformation prevention member includes a film, the film being formed of one of a polyethylene terephthalate-based material and an acryl-based material.

3. The display apparatus as set forth in claim 1, wherein the deformation prevention member includes a film, the film being formed of at least one of a polyimide, a poly(p-xylene) polymer, polymethylmethacrylate, a polyvinylalcohol, and a polyvinylphenol.

4. The display apparatus as set forth in claim 1, wherein the deformation prevention member includes a transparent deposition film, the transparent deposition film including at least one of amorphous silicon (a-Si) and silicon nitride (SiNx) deposited on a surface opposite to a light-emitting surface of the display panel.

5. The display apparatus as set forth in claim 1, further comprising an encapsulation member between the deformation prevention member and the display panel.

6. The display apparatus as set forth in claim 5, wherein the encapsulation member covers the display unit and includes one of an insulating substrate and a metal cover.

7. The display apparatus as set forth in claim 5, wherein the encapsulation member includes a coating film covering the display unit, the coating film including an insulating organic material.

8. The display apparatus as set forth in claim 1, wherein the display unit includes an organic light emitting diode.

9. A display apparatus, comprising:
a display panel including an array substrate and a display unit on the array substrate;
a polarizing film on at least one surface of the display panel; and
a deformation prevention member between the display panel and the polarizing film, the deformation prevention member preventing deformation of the display panel caused by the polarizing film.

10. The display apparatus as set forth in claim 9, wherein the deformation prevention member includes a film, the film being formed of one of a polyethylene terephthalate-based material and an acryl-based material.

11. The display apparatus as set forth in claim 9, wherein the deformation prevention member includes a film, the film being formed of at least one of a polyimide, a poly(p-xylene) polymer, polymethylmethacrylate, a polyvinylalcohol, and a polyvinylphenol.

12. The display apparatus as set forth in claim 9, wherein the deformation prevention member includes a transparent deposition film, the transparent deposition film including at least one of amorphous silicon (a-Si) and a silicon nitride (SiNx) deposited on a surface facing a light-emitting surface of the display panel.

13. The display apparatus as set forth in claim 9, wherein the display unit includes an organic light emitting diode.
